(19) United States
(12) Patent Application Publication
(10) Pub. No.: US 2023/0042018 A1
(43) Pub. Date: Feb. 9, 2023

(54) MULTI-CONTEXT ENTROPY CODING FOR COMPRESSION OF GRAPHS

(71) Applicant: GOOGLE LLC, Mountain View, CA (US)

(72) Inventors: Luca VERSARI, Mountain View, CA (US); Lulia COMSA, Mountain View, CA (US)

(21) Appl. No.: 17/758,851

(22) PCT Filed: Apr. 30, 2020
(86) PCT No.: PCT/US2020/030870

§ 371 Date: Jul. 14, 2022

Related U.S. Application Data
(60) Provisional application No. 62/975,722, filed on Feb. 12, 2020.

(51) Int. Cl. H03M 7/40; H03M 7/30

(52) U.S. Cl. CPC H03M 7/40; H03M 7/6005

(57) ABSTRACT

Example embodiments relate to using a multi-context entropy coder for encoding adjacency lists. A system may obtain a graph having data (or multiple graphs) and may compress the data of the graph using a multi -context entropy coder. The multi-context entropy coder may encode adjacency lists within the data such that each integer is assigned to a different probability distribution. For example, operating the multi-context entropy coder may involve using a combination of arithmetic coding, Huffman coding, and ANS. The assignment of integers to the probability distributions may depend on each integer’s role and/or previous values of a similar kind. By using multi -context entropy- coding, the computing system may increase compression ratio while maintaining similar processing speed.

### CROSS-REFERENCE TO RELATED APPLICATION

The present application claims priority to U.S. Provisional Pat. Application No. 62/975,722, filed Feb. 12, 2020, the entire contents of which are herein incorporated by reference.

### BACKGROUND

Data compression techniques are used to encode digital data into an alternative, compressed form with fewer bits than the original data, and then to decode (i.e., decompress) the compressed form when the original data is desired. The compression ratio of a particular data compression system is the ratio of the size (during storage or transmission) of the encoded output data to the size of the original data. Data compression techniques are increasingly used as the amount of data being obtained, transmitted, and stored in digital form increases substantially in many various fields. These techniques can help reduce resources required to store and transmit data.

Generally, data compression techniques can be categorized as lossless or lossy. Lossless compression reduces bits by identifying and eliminating statistical redundancy. No information is lost in lossless compression. Lossy compression involves reducing bits by removing unnecessary or less important information.

### SUMMARY

Example embodiments presented herein relate to systems and methods for compressing data, such as graph data, using multi-context entropy coding.

In a first example embodiment, a method is provided. The method involves obtaining, at a computing system, a graph having data and compressing, by the computing system, the data of the graph using a multi-context entropy coder. The multi-context entropy coder encodes adjacency lists within the data such that each integer is assigned to a different probability distribution.

In a second example embodiment, a system is provided. The system includes a computing system, a non-transitory computer readable medium, and program instructions stored on the non-transitory computer readable medium executable by the computing system to perform operations. The operations include obtaining a graph having data and compressing the data of the graph using a multi-context entropy coder. The multi-context entropy coder encodes adjacency lists within the data such that each integer is assigned to a different probability distribution.

In a third example embodiment, a non-transitory computer-readable medium configured to store instructions is provided. The program instructions may be stored in the data storage, and upon execution by a computing system may cause the computing system to perform operations in accordance with the first and second example embodiments.

In a fourth example embodiment, a system may include various means for carrying out each of the operations of the example embodiments above.

These as well as other embodiments, aspects, advantages, and alternatives will become apparent to those of ordinary skill in the art by reading the following detailed description, with reference where appropriate to the accompanying drawings. Further, it should be understood that this summary and other descriptions and figures provided herein are intended to illustrate embodiments by way of example only and, as such, that numerous variations are possible. For instance, structural elements and process steps can be rearranged, combined, distributed, eliminated, or otherwise changed, while remaining within the scope of the embodiments as claimed.

### BRIEF DESCRIPTION OF THE DRAWINGS

FIG. 1 is a block diagram of a computing system, according to one or more example embodiments.

FIG. 2 depicts a cloud-based server cluster, according to one or more example embodiments.

FIG. 3 depicts an Asymmetric Numeral System implementation, according to one or more example embodiments.

FIG. 4 depicts a Huffman coding implementation, according to one or more example embodiments.

FIG. 5 shows a flowchart for a method, according to one or more example embodiments.

FIG. 6 illustrates a schematic diagram of a computer program, according to example embodiments.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features. Other embodiments can be utilized, and other changes can be made, without departing from the scope of the subject matter presented herein.

Thus, the example embodiments described herein are not meant to be limiting. Aspects of the present disclosure, as generally described herein, and illustrated in the figures, can be arranged, substituted, combined, separated, and designed in a wide variety of different configurations, all of which are contemplated herein. Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

### 1. Overview

Graphs that are processed by modem computing systems have an increasingly large size, often growing faster than the resources that are available to handle them. This might require implementing compression schemes that allow access to the data without decompressing the full graph.

Current implementations of such structures compress graphs by storing adjacency lists using other lists as a reference. Edges can be copied from the reference or encoded using universal integer codes. While this scheme might achieve useful compression ratios, it does not adapt well to variations in the source data.

Example embodiments may involve the use of multi-context entropy coding for encoding adjacency lists. Multi-context entropy coding may involve the use of multiple compression schemas, such as arithmetic coding, Huffman coding, or Asymmetric Numeral Systems (ANS). For example, a system may use a combination of Huffman coding and ANS. Huffman coding may be used to create files that support access to the neighborhood of any node and ANS may be used to create files that may only be decoded in their entirety. In addition, the system may enable symbols to be encoded to be split into multiple contexts. For each context, a different probability distribution may be used by the system, which can allow for more precise encoding when symbols are assumed to belong to different probability distributions.

In some embodiments, a system may use multi-context entropy coding such that each integer is assigned to a different (stored) probability distribution depending on its role. For example, multi-context entropy coding may enable lengths of blocks to be copied versus skipped from a reference list. The multi-context entropy coding may also involve each integer being assigned to a different probability distribution depending on previous values of a similar kind. For example, a different probability distribution can be chosen for a given delta depending on the magnitude of the previous delta. The use of multi-context entropy coding can enable the system to achieve compression ratio improvements over existing techniques while also having similar processing speeds. Further examples are described herein.

### 2. Example Systems

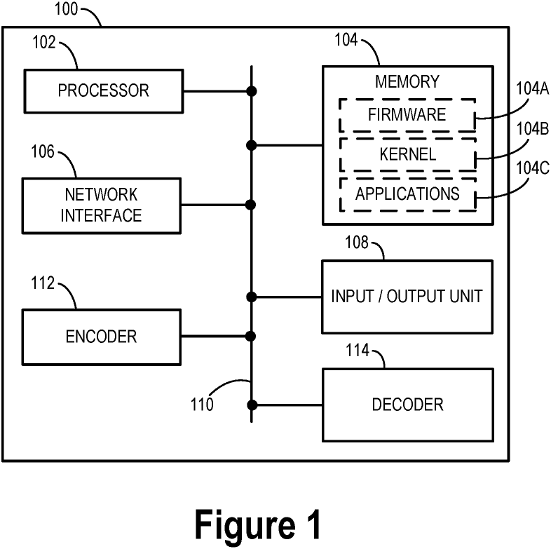

FIG. 1 is a simplified block diagram exemplifying a computing system 100, illustrating some of the components that could be included in a computing device arranged to operate in accordance with the embodiments herein. Computing system 100 could be a client device (e.g., a device actively operated by a user), a server device (e.g., a device that provides computational services to client devices), or some other type of computational platform. Some server devices may operate as client devices from time to time in order to perform particular operations, and some client devices may incorporate server features.

In this example, computing system 100 includes processor 102, memory 104, network interface 106, and an input / output unit 108, all of which may be coupled by a system bus 110 or a similar mechanism. In some embodiments, computing system 100 may include other components and/or peripheral devices (e.g., detachable storage, printers, and so on).

Processor 102 may be one or more of any type of computer processing element, such as a central processing unit (CPU), a co-processor (e.g., a mathematics, graphics, or encryption co-processor), a digital signal processor (DSP), a network processor, and/or a form of integrated circuit or controller that performs processor operations. In some cases, processor 102 may be one or more single-core processors. In other cases, processor 102 may be one or more multi-core processors with multiple independent processing units. Processor 102 may also include register memory for temporarily storing instructions being executed and related data, as well as cache memory for temporarily storing recently-used instructions and data.

Memory 104 may be any form of computer-usable memory, including but not limited to random access memory (RAM), read-only memory (ROM), and non-volatile memory. This may include flash memory, hard disk drives, solid state drives, rewritable compact discs (CDs), re-writable digital video discs (DVDs), and/or tape storage, as just a few examples.

Computing system 100 may include fixed memory as well as one or more removable memory units, the latter including but not limited to various types of secure digital (SD) cards. Thus, memory 104 represents both main memory units, as well as long-term storage. Other types of memory may include biological memory.

Memory 104 may store program instructions and/or data on which program instructions may operate. By way of example, memory 104 may store these program instructions on a non-transitory, computer-readable medium, such that the instructions are executable by processor 102 to cany out any of the methods, processes, or operations disclosed in this specification or the accompanying drawings.

As shown in FIG. 1, memory 104 may include firmware 104A, kernel 104B, and/or applications 104C. Firmware 104A may be program code used to boot or otherwise initiate some or all of computing system 100. Kernel 104B may be an operating system, including modules for memory management, scheduling and management of processes, input / output, and communication. Kernel 104B may also include device drivers that allow the operating system to communicate with the hardware modules (e.g., memory units, networking interfaces, ports, and busses), of computing system 100. Applications 104C may be one or more user-space software programs, such as web browsers or email clients, as well as any software libraries used by these programs. In some examples, applications 104C may include one or more neural network applications. Memory 104 may also store data used by these and other programs and applications.

Network interface 106 may take the form of one or more wireline interfaces, such as Ethernet (e.g., Fast Ethernet, Gigabit Ethernet, and so on). Network interface 106 may also support communication over one or more non-Ethernet media, such as coaxial cables or power lines, or over wide-area media, such as Synchronous Optical Networking (SONET) or digital subscriber line (DSL) technologies. Network interface 106 may additionally take the form of one or more wireless interfaces, such as IEEE 802.11 (Wifi), BLUETOOTH®, global positioning system (GPS), or a wide-area wireless interface. However, other forms of physical layer interfaces and other types of standard or proprietary communication protocols may be used over network interface 106. Furthermore, network interface 106 may comprise multiple physical interfaces. For instance, some embodiments of computing system 100 may include Ethernet, BLUETOOTH®, and Wifi interfaces.

Input / output unit 108 may facilitate user and peripheral device interaction with computing system 100 and/or other computing systems. Input / output unit 108 may include one or more types of input devices, such as a keyboard, a mouse, one or more touch screens, sensors, biometric sensors, and so on. Similarly, input / output unit 108 may include one or more types of output devices, such as a screen, monitor, printer, and/or one or more light emitting diodes (LEDs). Additionally or alternatively, computing system 100 may communicate with other devices using a universal serial bus (USB) or high-definition multimedia interface (HDMI) port interface, for example.

Encoder 112 represents one or more encoders that computing system 100 may use to perform compression techniques described herein, such as multi-context entropy encoding. In some examples, encoder 112 may include multiple encoders configured to perform sequentially and/or simultaneously. Encoder 112 may also be a single encoder capable of encoding data from multiple data structures (e.g., data) simultaneously. In some examples, encoder 112 may represent one or more encoders positioned remotely from computing system 100.

Decoder 114 represents one or more encoders that computing system 100 may use to perform decompression techniques described herein. In some examples, decoder 114 may include multiple decoders configured to perform sequentially and/or simultaneously. Decoder 114 may also be a single decoder capable of decoding data from multiple compressed data sources simultaneously. In some examples, decoder 114 may represent one or more encoders positioned remotely from computing system 100.

Encoder 112 and decoder 114 may communicate with other components of computing system 100, such as memory 104. In addition, encoder 112 and decoder 114 may represent software and/or hardware within some embodiments.

In some embodiments, one or more instances of computing system 100 may be deployed to support a clustered architecture. The exact physical location, connectivity, and configuration of these computing devices may be unknown and/or unimportant to client devices. Accordingly, the computing devices may be referred to as “cloud-based” devices that may be housed at various remote data center locations. In addition, computing system 100 may enable performance of embodiments described herein, including using neural networks and implementing a neural light transport.

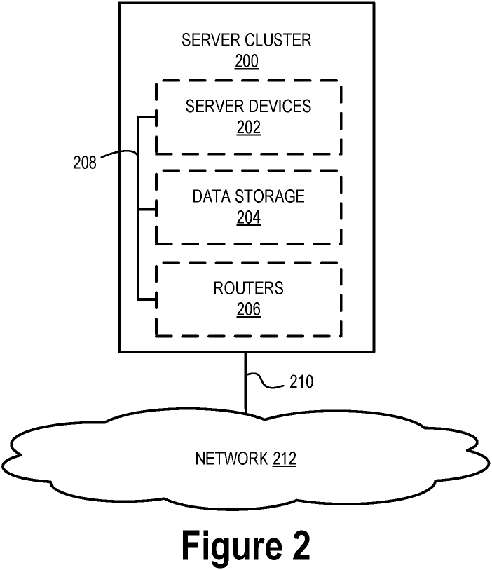

FIG. 2 depicts a cloud-based server cluster 200 in accordance with example embodiments. In FIG. 2, one or more operations of a computing device (e.g., computing system 100) may be distributed between server devices 202, data storage 204, and routers 206, all of which may be connected by local cluster network 208. The number of server devices 202, data storages 204, and routers 206 in server cluster 200 may depend on the computing task(s) and/or applications assigned to server cluster 200. In some examples, server cluster 200 may perform one or more operations described herein, including the use of neural networks and implementation of a neural light transport function.

Server devices 202 can be configured to perform various computing tasks of computing system 100. For example, one or more computing tasks can be distributed among one or more of server devices 202. To the extent that these computing tasks can be performed in parallel, such a distribution of tasks may reduce the total time to complete these tasks and return a result. For the purpose of simplicity, both server cluster 200 and individual server devices 202 may be referred to as a “server device.” This nomenclature should be understood to imply that one or more distinct server devices, data storage devices, and cluster routers may be involved in server device operations. In addition, server devices 202 may be configured to perform operations described herein, including multi-context entropy coding.

Data storage 204 may be data storage arrays that include drive array controllers configured to manage read and write access to groups of hard disk drives and/or solid state drives. The drive array controllers, alone or in conjunction with server devices 202, may also be configured to manage backup or redundant copies of the data stored in data storage 204 to protect against drive failures or other types of failures that prevent one or more of server devices 202 from accessing units of cluster data storage 204. Other types of memory aside from drives may be used.

Routers 206 may include networking equipment configured to provide internal and external communications for server cluster 200. For example, routers 206 may include one or more packet-switching and/or routing devices (including switches and/or gateways) configured to provide (i) network communications between server devices 202 and data storage 204 via cluster network 208, and/or (ii) network communications between the server cluster 200 and other devices via communication link 210 to network 212.

Additionally, the configuration of cluster routers 206 can be based at least in part on the data communication requirements of server devices 202 and data storage 204, the latency and throughput of the local cluster network 208, the latency, throughput, and cost of communication link 210, and/or other factors that may contribute to the cost, speed, fault-tolerance, resiliency, efficiency and/or other design goals of the system architecture.

As a possible example, data storage 204 may include any form of database, such as a structured query language (SQL) database. Various types of data structures may store the information in such a database, including but not limited to tables, arrays, lists, trees, and tuples. Furthermore, any databases in data storage 204 may be monolithic or distributed across multiple physical devices.

Server devices 202 may be configured to transmit data to and receive data from cluster data storage 204. This transmission and retrieval may take the form of SQL queries or other types of database queries, and the output of such queries, respectively. Additional text, images, video, and/or audio may be included as well. Furthermore, server devices 202 may organize the received data into web page representations. Such a representation may take the form of a markup language, such as the hypertext markup language (HTML), the extensible markup language (XML), or some other standardized or proprietary format. Moreover, server devices 202 may have the capability of executing various types of computerized scripting languages, such as but not limited to Perl, Python, PHP Hypertext Preprocessor (PHP), Active Server Pages (ASP), JavaScript, and so on. Computer program code written in these languages may facilitate the providing of web pages to client devices, as well as client device interaction with the web pages.

### 3. Entropy Coding

Entropy coding is a type of lossless coding to compress digital data by representing frequently occurring patterns with few bits and rarely occurring patterns with many bits. As such, an entropy encoding technique can be a lossless data compression scheme that is independent of the specific characteristics of the medium.

The process of entropy coding (EC) can be split into modeling and coding. Modeling may involve assigning probabilities to the symbols and coding may involve producing a bit sequence from these probabilities. As established in Shannon’s source coding theorem, there is a relationship between a symbol’s probability and its corresponding bit sequence. For example, a symbol with probability p is assigned a bit sequence of length -log(p). In order to achieve a good compression rate, probability estimation may be used. In particular, because the model is responsible for the probability of each symbol, modeling can be a critical task in data compression.

One entropy coding technique may involve creating and assigning a unique prefix-free code to each unique symbol that occurs in the input. These entropy encoders can then compress data by replacing each fixed-length input symbol with the corresponding variable-length prefix-free output code word. The length of each code word is approximately proportional to the negative logarithm of the probability. In some examples, the optimal code length for a symbol is -log_{b} P where b is the number of symbols used to make output codes and P is the probability of the input symbol.

Entropy coding can be achieved by different coding schemes. A common scheme, which uses a discrete number of bits for each symbol, is Huffman coding. A different approach is arithmetic coding, which can output a bit sequence representing a point inside an interval. The interval can be built recursively by the probabilities of the encoded symbols.

Another compression scheme is Asymmetric Numeral Systems (ANS). ANS is a lossless compression algorithm or schema that inputs a list of symbols from some finite set and outputs one or more finite numbers. Each symbol s has a fixed known probability of pₛ of occurring in the list. The ANS schema tries to assign each list a unique integer so that more probable lists get smaller integers. Computing system 100 may use ANS, which can combine the compression ratio of arithmetic coding with a processing costs similar to that of Huffman coding.

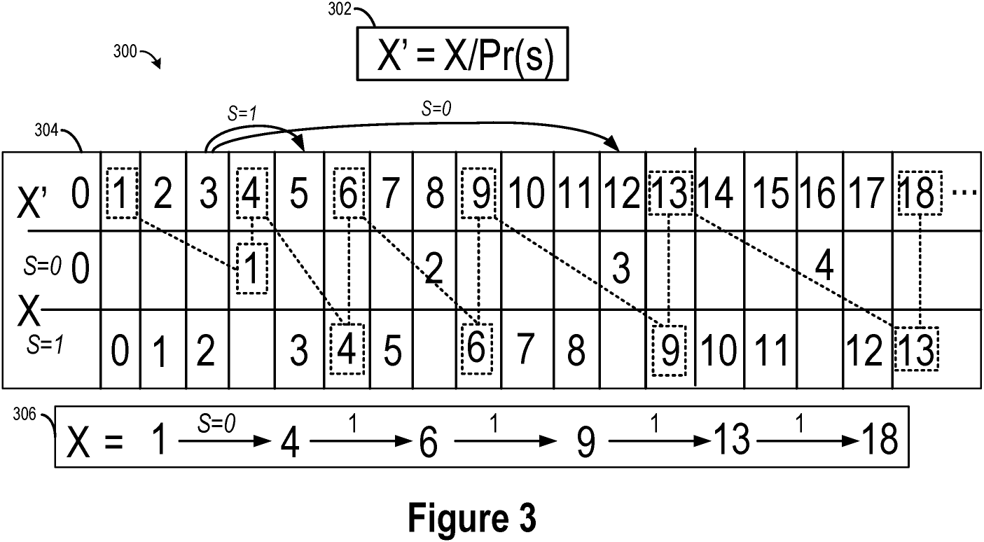

FIG. 3 depicts an asymmetric numeral system implementation, according to one or more example embodiments. The ANS 300 may involve encoding information into a single natural number x, which can be interpreted as containing log₂(x) bits of information. Adding information from a symbol of probability p increases the informational content to

$${log}_{2} \left(x\right) + {log}_{2} \left(\frac{1}{p}\right) = {log}_{2} \left(x / p\right) .$$

As a result, the new number containing both information can correspond to equation 302 as follows:

$${x}^{′} = x / p .$$

As shown in FIG. 3, the equation 302 can be used by the system 300 to add information in the least significant position with a coding rule that specifies “x goes to the x-th appearance of subset of natural numbers corresponding to currently encoded symbol.” In the example shown in FIG. 3, the chart 304 shows encoding a sequence (01111) into a natural number 18, which is smaller than 47 that would be obtained using a standard binary system. The system 300 may achieve the smaller natural number 18 due to a better agreement with frequencies of sequence to encode. As such, the system 300 can allow storing information in a single natural number rather than two numbers that define a range as indicated in the X sub chart 306 further shown in FIG. 3.

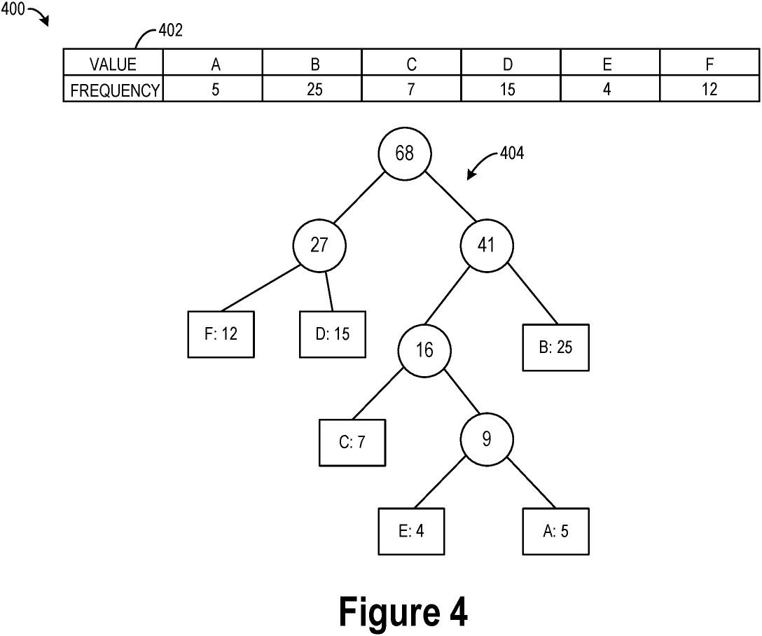

FIG. 4 depicts a Huffman coding implementation, according to one or more example embodiments. As discussed above, Huffman coding may be used with integer length codes and may be depicted via a Huffman tree. The system 400 may use Huffman coding for the construction of minimum redundancy codes. As such, the system 400 may use Huffman coding for data compression that minimizes cost, time, bandwidth, and storage space for transmitting data from one place to another.

In the embodiment shown in FIG. 4, the system 400 shows a chart 402 that includes nodes arranged according to value and corresponding frequency. The system 400 may be configured to search for the two nodes within the chart 402 that have the lowest frequency and are not yet assigned to a parent node. The two nodes may be coupled together to a new interior node and the frequencies may be added by the system 400 to assign the total to the new interior node. The system 400 may repeat the process searching for the next two nodes with the lowest frequency that are not yet assigned to a parent node until all nodes are combined together in a root node.

The system 400 may initially arrange all the values in ascending order of the frequencies according to a Huffman coding technique. For example, the values may be rearranged in the following order: “E, A, C, F, D, B.” After reordering, the system 400 may subsequently insert the first two values that have the smallest frequencies (i.e., E and A) as a first portion of the Huffman tree 404. As shown, the frequencies of E:4 and A:5 add up to a total frequency of 9 (i.e., EA:9) as shown in the Huffman tree 404.

Next, the system 400 may involve combining the nodes with the next smallest frequencies, which correspond to C:7 and EA:9. Adding these together create CEA:16 as shown in the Huffman tree 404. The system 400 may subsequently create a subtree for the next two nodes with the smallest frequencies, which are F:12 and D:15. This results in FD:27 as shown. The system 400 may then combine the next two smallest nodes corresponding to CEA:16 and B:25 to produce CEAB:41. Lastly, the system 400 may combine the subtrees together FD:27 and CEAB:41 to create value FDCEAB having a frequency of 68 as shown in total by the Huffman tree 404 represented in FIG. 4.

Although both Huffman coding and ANS offer compression benefits, there are some situations where a computing system may benefit from using a combination during data compression. In particular, computing system 100 may use multi-context entropy coding for encoding adjacency lists. Multi-context entropy coding may involve the use of multiple schemas, such as arithmetic coding, Huffman coding, or ANS. For example, computing system 100 may use both Huffman coding when creating files that support access to the neighborhood of any node, and may use ANS when creating files that may only be decoded in their entirety. In both cases, symbols to be encoded may be split into multiple contexts. For each context, a different probability distribution may be used, which can allow for more precise encoding when symbols are assumed to belong to different probability distributions.

Computing system 100 may use multi-context entropy coding such that each integer is assigned to a different (stored) probability distribution depending on its role. For example, multi-context entropy coding may enable lengths of blocks to be copied versus skipped from a reference list. The multi-context entropy coding may also involve each integer being assigned to a different probability distribution depending on previous values of a similar kind. For example, a different probability distribution can be chosen for a given delta depending on the magnitude of the previous delta. The use of multi-context entropy coding can enable computing system 100 to achieve compression ratio improvements over existing techniques while also having similar processing speeds.

In some instances, a variant of ANS may be used by computing system 100 during multi-context entropy coding. The variant of ANS may be based on a variant frequently used in a particular format, such as JPEG XL. This selection can allow a memory usage per context proportional to the maximum number of symbols that can be encoded by the stream as opposed to other variants, which may require memory proportional to the size of the quantized probability for each distribution. As a result, the technique can enable better cache locality when decoding is performed by computing system 100.

One potential disadvantage of ANS and other encoding schemes that can use a non-integer number of bits per encoded symbol (e.g., arithmetic coding) when access to single adjacency lists is involved might be that a system using ANS might be required to keep an internal state. For decoding to successfully be able to resume from a given position in the bitstream, it might also be necessary to be able to recover the state of the entropy coder at that point of the bitstream, which can cause a significant per-node overhead. Thus, when random access to adjacency lists is required, computing system 100 may switch to using Huffman coding instead of ANS. Thus, the ability to switch between schemas when using multi-context entropy coding can help computing system 100 avoid drawbacks associated with individual schemas.

Both Huffman coding and ANS can utilize a reduced alphabet size. When computing system 100 is performing a task that involves encoding integers of arbitrary length, the use of a distinct symbol for each integer may not be feasible due to the resources required. As a result, the system 100 may opt to use a hybrid integer encoding, which may be defined by two parameters h and k. In particular, when defining the two parameters, k may be greater than or equal to h, and h may be greater than or equal to 1 (k ≥ h ≥ 1) .

In some embodiments, computing system 100 may store each integer in the [0, 2^{k}) range directly as a symbol. In addition, any other integer may then be stored by encoding the index of the highest bit (x) into the symbol as well as the h-1 following bits (b) in the base-2 representation of the number and then by storing all the remaining bits directly in the bit stream without using any entropy coding. The resulting symbol can thus be represented as follows

$${2}^{k} + \left(x - k - 1\right) ⋅ {2}^{h - 1} + b$$

Computing system 100 may use the equation 1 to represent r-bit numbers with at most 2^{k} + (r - k - 1) · 2^{h-1} symbols. To illustrate an example, when k = 4 and h = 2, computing system 100 may have numbers up to 15 that can be encoded as the corresponding symbol with no extra bits. In addition, 23 can be encoded as symbol 16 (the highest set bit is in position 5, and the following bit is 0), followed by three extra bits with value 111. As a further example, value 33 may be encoded as symbol 18 followed by four extra bits with value 0001.

### 4. Example Graph Compression Methods

Computing system 100 may perform graph compression using multiple-context encoding code. The format may achieve desired compression ratios by employing the following representation of the adjacency list of node n. In the following, window size (W) and minimum interval length (L) may be used as global parameters. Each list may start with the degree of n. If the degree is strictly positive, it may be followed by a reference number r, which can be a number in [1, W). This may indicate that the list is represented by referencing the adjacency list of node n-r (called reference list, or 0, meaning that the list is represented without reference any other list).

In addition, if r is strictly positive, it may be followed by a list of integers indicating that the indices where the reference list should be split to obtain contiguous blocks. Blocks in even positions may represent edges that should be copied to the current list. The format contains, in this order, the number of blocks, the length of the first block, and the length minus 1 of all the following blocks (since no block except the first may be empty). The last block may not be stored because its length can be deduced from the length of the reference list. A list of intervals may follow with each interval represented by a pair s, I. This may mean that there should be an edge towards all the nodes in the interval [s, l + L).

Further, a list of residuals may be encoded. For instance, the list of residuals may be encoded of implicit length since its length can be deduced by the degree, the number of copied edges, and the number of edges represented by intervals. This list may represent all the edges that were not encoded using the other schemes and may also be delta-coded. In particular, the first residual may be encoded as the delta with respect to the current node, and all subsequent residuals may be represented as the delta with respect to the previous residual minus 1.

In some instances, the representation of the first residual may produce negative numbers. To address this issue, computing system 100 may encode the first residual as follows:

$$x \to \left\{\begin{matrix}2 ⋅ x & \text{if} \text{} \text{x} \geq 0 \\ - 2 ⋅ x - 1 & \text{if} \text{} \text{x} < 0 \text{}\end{matrix}\right.$$

This is an easy to reverse bijection between integers and natural numbers. To enable fast access to single adjacency lists, the schema may limit the length of the reference chain of each node. In particular, a reference chain may be a sequence of nodes (e.g., n₁, .... , nᵣ) such that node nᵢ₊₁ uses node nᵢ as a reference with r representing the length of the reference chain. The schema can enable every reference chain to have a length at most R, where R is a global parameter.

The schema can represent the resulting sequence of non-negative integers using ζcodes, such as a set of universal codes particularly suited to represent integers following a power-law distribution.

In some embodiments, computing system 100 may use the schema above with one or more modifications. As previously indicated herein, computing system 100 may use entropy coding for representing non-negative integers.

In an embodiment, computing system 100 may use the schema with degrees represented via delta-coding. The delta-coding may be used because the representation of node degrees can take a significant amount of bits in the final compressed file. As this may produce negative numbers, deltas may be represented using the transformation of equation 1 shown above.

Delta-coding across multiple adjacency lists can be hostile to enabling access to any adjacency lists without decoding the rest of the graph first. In light of this potential issue, when access to single lists is requested, the schema may split the graph into chunks. Each chunk may have a fixed length “C”. As a result, delta-coding of degrees can then be performed inside of a single chunk.

Computing system 100 may also modify the residual representation used by the schema. Residuals in the schema are encoded via usage of delta-coding, but the chosen representation does not exploit the fact that an edge might already be represented by block copies, for example.

To illustrate an example, consider a case in which an adjacency list contains nodes 2, 3, 4, 6, 7, and edges 3, 4, and 6 are already represented by block copies. Residuals would then be 2 and 7, and the second residual would be represented as follows: 7 - 2 - 1 = 4. However, in this example, reading 0, 1 or 3 from the compressed file may result in an edge value of 3, 4 or 6, which would be superfluous. Therefore, computing system 100 may modify the delta-coding of residuals by removing edges that are already known to be present from the length of the gap. In this case, residual edge 7 would be represented as 2.

In addition, as a form of simplification, the representation for interval may be removed and replaced with run-length encoding of zero gaps. This change was made possible via the entropy coding improvements previously described herein.

In particular, when reading residuals, as soon as a sequence of exactly Z zero gaps is read, another integer is read to represent the subsequent number of zero gaps, which are not otherwise represented in the compressed representation. Since ANS may not require an integer of bits per symbol and can also enable efficiency representation of sequence of zeros, the system may set Z = ∞if access to single adjacency lists is not required.

The encoder of computing system 100 may use one or more algorithms to select a reference list for use during compression. In some instances, access to single lists is not required. In this case, there might not be limitation on the length of the reference chain used by a single node, and thus the system can safely choose the reference list that gives the optimum compression out of all the lists available in the current window (i.e., all adjacency lists of the W preceding nodes).

The system may estimate the number of bits that an algorithm may use to compress an adjacency list using a given reference. Since the system may use an adaptive entropy model, the estimation may be impacted as choices for one list might affect probabilities for all other options.

Thus, the system may use the same iterative approach used by the scheme. This may involve initializing symbol probabilities with a simple fixed module (e.g., all symbols have equal probability), then selecting reference lists assuming these will be the final costs. The system may then compute symbol probabilities given by the chosen reference lists and repeat the procedure with the new probability distribution. This process may then be repeated a constant number of times.

When access to single lists is requested, more care may be required to properly select the reference lists while avoiding too long reference chains. A simple solution may be to discard all lists in the window that would produce a too long reference chain, without changing decisions taken in previous nodes.

The system may use a different strategy, which may involve initially building a tree T of references. The tree T of references may disregard the maximum reference chain length constraints, where each tree edge is weighted with the number of bits that are saved by using the parent node as a reference for the child node. In some instances, the optimal tree can easily be constructed by the greedy algorithm that is used when no access to single lists is required. Then, the system 100 may solve a dynamic programming problem on the resulting tree. This can produce a result that indicates a maximum weight for the sub-forest F that is contained in the tree and does not have paths of length R + 1. If this procedure results in some paths that are shorter than R, the system may try to extend them in some way.

The above technique can be proved to provide the following approximation of the maximum number of bits to be saved as follows:

$$1 - \frac{1}{R + 1}$$

If the total weight W_{T} of T is considered, the weight W_{F} of the optimal sub-forest extracted by the dynamic programming algorithm and the weight W_{O} of the forest that represents the best possible choice of reference nodes, the system may provide the following.

First, W_{T} may be greater than or equal to W_{O} (W_{T} ≥ W_{O}), as T is the optimal solution for a problem with less constraints. If

$${W}_{F} \geq \left(1 - \frac{1}{R + 1}\right) {W}_{T}$$

, the system may split the edges of T in R + 1 groups depending on their distance from the root modulo R + 1, then it is clear that deleting one such group is sufficient to satisfy the constraint of maximum path length. In particular, the forest obtained by erasing the set of edges of minimum total weight will have a weight of at least

$$\left(1 - \frac{1}{R + 1}\right) {W}_{T}$$

. As W_{F} may be the optimal forest that satisfies the maximum path length constraint, its weight may be at least as large accordingly. This gives the approximation bound as follows:

$${W}_{o} \geq {W}_{F} \geq \left(1 - \frac{1}{R + 1}\right) {W}_{o}$$

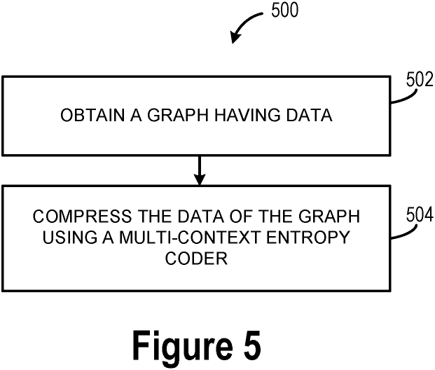

FIG. 5 is a flow chart of a method, according to one or more example embodiments. Method 300 represents an example method that may include one or more operations, functions, or actions, as depicted by one or more of blocks 502 and 504, each of which may be carried out by any of the systems shown in FIGS. 1-4, among other possible systems.

Those skilled in the art will understand that the flowchart described herein illustrates functionality and operations of certain implementations of the present disclosure. In this regard, each block of the flowchart may represent a module, a segment, or a portion of program code, which includes one or more instructions executable by one or more processors for implementing specific logical functions or steps in the process. The program code may be stored on any type of computer readable medium, for example, such as a storage device including a disk or hard drive.

In addition, each block may represent circuitry that is wired to perform the specific logical functions in the process. Alternative implementations are included within the scope of the example implementations of the present application in which functions may be executed out of order from that shown or discussed, including substantially concurrent or in reverse order, depending on the functionality involved, as would be understood by those reasonably skilled in the art.

At block 502, method 500 involves obtaining a graph having data. For instance, a computing system may obtain various types of graphs. The graphs may be obtained from different sources, such as other computing systems, internal memory, and/or external memory.

At block 504, method 500 involves compressing the data of the graph using a multi-context entropy coder. The multi-context entropy coder encodes adjacency lists within the data such that each integer is assigned to a different probability distribution.

In some examples, compressing the data may involve compressing the data of the graph using the multi-context entropy coder for storage in memory. In addition, compressing the data may involve compressing the data of the graph using the multi-context entropy coder for transmission to at least one computing device. In some examples, compressing the data of the graph may involve using a combination of Huffman coding and ANS.

In further examples, method 500 may further involve obtaining a second graph having second data and compressing the second data of the graph using the multi-context entropy coder. In some instances, compressing the second data of the graph is performed simultaneously with compressing the data of the graph.

In some embodiments, method 500 may further involve decompressing the compressed data of the graph using a decoder. The decoder may be configured to decode data encoded by the multi-context entropy coder. In some instances, multiple decoders may be used. The decoders and/or encoders may be transmitted and received between different types of devices, such as servers, CPUs, GPUs, etc.

In some embodiments, method 500 may further involve, while compressing the data of the graph using the multi-context entropy coder, determining a processing speed associated with the multi-context entropy coder. Method 500 may further involve comparing the processing speed to a threshold processing speed and, based on the comparing the processing speed to the threshold processing speed, adjusting operation of the multi-context entropy coder. For example, a system may determine that the processing speed is below the threshold processing speed and, based on determining that the processing speed is below the threshold processing speed, decreasing an operation rate of the multi-context entropy coder.

In further embodiments, different weights may be determined and applied by computing system 100 when compressing or decompressing one or more graphs. For example, computing system 100 may assign greater weights to compressing using Huffman compression than the weights assigned to compression via ANS compression. The compression may also involve switching between each compression technique or simultaneous performance of the techniques.

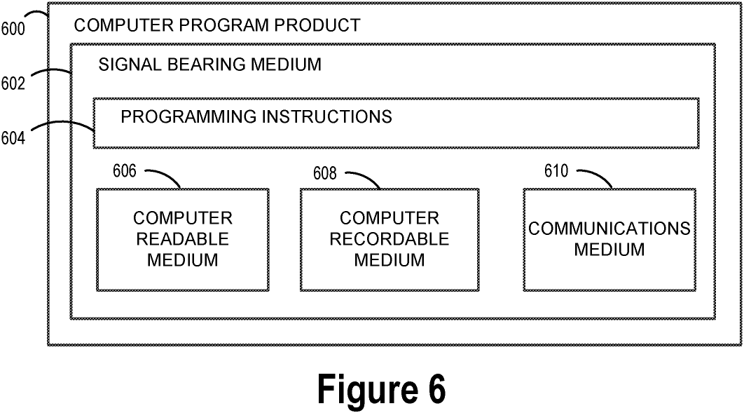

FIG. 6 is a schematic illustrating a conceptual partial view of an example computer program product that includes a computer program for executing a computer process on a computing device, arranged according to at least some embodiments presented herein. In some embodiments, the disclosed methods may be implemented as computer program instructions encoded on a non-transitory computer-readable storage media in a machine-readable format, or on other non-transitory media or articles of manufacture.

In one embodiment, example computer program product 600 is provided using signal bearing medium 602, which may include one or more programming instructions 604 that, when executed by one or more processors may provide functionality or portions of the functionality described above with respect to FIGS. 1-5. In some examples, the signal bearing medium 602 may encompass a non-transitory computer-readable medium 606, such as, but not limited to, a hard disk drive, a Compact Disc (CD), a Digital Video Disk (DVD), a digital tape, memory, etc. In some implementations, the signal bearing medium 602 may encompass a computer recordable medium 608, such as, but not limited to, memory, read/write (R/W) CDs, R/W DVDs, etc.

In some implementations, the signal bearing medium 602 may encompass a communications medium 610, such as, but not limited to, a digital and/or an analog communication medium (e.g., a fiber optic cable, a waveguide, a wired communications link, a wireless communication link, etc.). Thus, for example, the signal bearing medium 602 may be conveyed by a wireless form of the communications medium 610.

The one or more programming instructions 604 may be, for example, computer executable and/or logic implemented instructions. In some examples, computing system 100 of FIG. 1 may be configured to provide various operations, functions, or actions in response to the programming instructions 604 conveyed to the computing system 100 by one or more of the computer readable medium 606, the computer recordable medium 608, and/or the communications medium 610.

The non-transitory computer readable medium could also be distributed among multiple data storage elements, which could be remotely located from each other. Alternatively, the computing device that executes some or all of the stored instructions could be another computing device, such as a server.

### 5. Conclusion

Implementations of this disclosure provide technological improvements that are particular to computer technology, for example, those concerning analysis of large scale data files with thousands of parameters. Computer-specific technological problems, such as enabling formatting of data into normalized forms for parameter reasonability analysis, can be wholly or partially solved by implementations of this disclosure. For example, implementation of this disclosure allows for data received from many different types of sensors to be formatted and reviewed for accuracy and reasonableness in a very efficient manner, rather than using manual inspection. Source data files including outputs from the different types of sensors, such as outputs concatenated together in the single file, can be processed together by one computing device in one computing processing transaction, rather than by separate devices per sensor output or by separate computing transactions. This is also very beneficial to enable review and comparisons of combinations of outputs of the different sensors to provide further insight into reasonableness of the data that cannot be performed when processing sensor outputs individually. Implementations of this disclosure can thus introduce new and efficient improvements in the ways in which data is analyzed by selectively applying appropriate translation maps to the data for batch processing of sensor outputs.

The systems and methods of the present disclosure further address problems particular to computer networks, for example, those concerning the processing of source file(s) including data received from various sensors for comparison with expected data (generated as a result of cause-and-effect analysis per each sensor reading) as found within multiple databases. These computing network-specific issues can be solved by implementations of the present disclosure. For example, by identifying a translation map and applying the map to the data, a common format can be associated with multiple source files for a more efficient reasonability check. The source file can be processed using substantially fewer resources than as currently performed manually, and increases accuracy levels due to usage of a parameter rules database that can otherwise be applied to the normalized data. The implementations of the present disclosure thus introduce new and efficient improvements in the ways in which databases can be applied to data in source data files to improve a speed and/or efficiency of one or more processor-based systems configured to support or utilize the databases.

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims.

The above detailed description describes various features and functions of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, functions described as steps, blocks, transmissions, communications, requests, responses, and/or messages can be executed out of order from that shown or discussed, including substantially concurrent or in reverse order, depending on the functionality involved. Further, more or fewer blocks and/or functions can be used with any of the ladder diagrams, scenarios, and flow charts discussed herein, and these ladder diagrams, scenarios, and flow charts can be combined with one another, in part or in whole.

A step or block that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical functions or actions in the method or technique. The program code and/or related data can be stored on any type of computer readable medium such as a storage device including a disk, hard drive, or other storage medium.

The computer readable medium can also include non-transitory computer readable media such as computer-readable media that store data for short periods of time like register memory, processor cache, and random access memory (RAM). The computer readable media can also include non-transitory computer readable media that store program code and/or data for longer periods of time. Thus, the computer readable media may include secondary or persistent long term storage, like read only memory (ROM), optical or magnetic disks, compact-disc read only memory (CD-ROM), for example. The computer readable media can also be any other volatile or non-volatile storage systems. A computer readable medium can be considered a computer readable storage medium, for example, or a tangible storage device.

Moreover, a step or block that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

Additionally, any enumeration of elements, blocks, or steps in this specification or the claims is for purpose of clarity. Thus, such enumeration should not be interpreted to require or imply that these elements, blocks, or steps adhere to a particular arrangement or are carried out in a particular order.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A method comprising:
obtaining, at a computing system, a graph having data; and
compressing, by the computing system, the data of the graph using a multi-context entropy coder, wherein the multi-context entropy coder encodes adjacency lists within the data such that each integer is assigned to a different probability distribution.

2. The method of claim 1, wherein compressing the data of the graph using the multi-context entropy coder comprises:
compressing the data of the graph using the multi-context entropy coder for storage in memory.

3. The method of claim 1, wherein compressing the data of the graph using the multi-context entropy coder comprises:
compressing the data of the graph using the multi-context entropy coder for transmission to at least one computing device.

4. The method of claim 1, wherein compressing the data of the graph using the multi-context entropy coder comprises:
compressing the data of the graph using a combination of Huffman coding and Asymmetric numeral systems (ANS).

5. The method of claim 1, further comprising:
obtaining a second graph having second data; and
compressing the second data of the graph using the multi-context entropy coder, wherein compressing the second data of the graph is performed simultaneously with compressing the data of the graph.

6. The method of claim 1, further comprising:
decompressing compressed data of the graph using a decoder, wherein the decoder is configured to decode data encoded by the multi-context entropy coder.

7. A system comprising:
a computing system;
a non-transitory computer readable medium; and
program instructions stored on the non-transitory computer readable medium, wherein the program instructions are executable by the computing system to perform operations comprising:
obtaining a graph having data; and
compressing the data of the graph using a multi-context entropy coder,
wherein the multi-context entropy coder encodes adjacency lists within the data such that each integer is assigned to a different probability distribution.

8. The system of claim 7, wherein compressing the data of the graph using the multi-context entropy coder comprises:
compressing the data of the graph using the multi-context entropy coder for storage in memory.

9. The system of claim 7, wherein compressing the data of the graph using the multi-context entropy coder comprises:
compressing the data of the graph using the multi-context entropy coder for transmission to at least one computing device.

10. The system of claim 7, wherein compressing the data of the graph using the multi-context entropy coder comprises:
compressing the data of the graph using a combination of Huffman coding and Asymmetric numeral systems (ANS).

11. The system of claim 7, wherein the operations further comprise:
obtaining a second graph having second data; and
compressing the second data of the graph using the multi-context entropy coder, wherein compressing the second data of the graph is performed simultaneously with compressing the data of the graph.

12. The system of claim 7, further comprising:
decompressing compressed data of the graph using a decoder, wherein the decoder is configured to decode data encoded by the multi-context entropy coder.

13. A non-transitory computer readable medium having stored therein instructions executable by one or more processors to cause a computing system to perform functions comprising:
obtaining a graph having data; and
compressing the data of the graph using a multi-context entropy coder, wherein the multi-context entropy coder encodes adjacency lists within the data such that each integer is assigned to a different probability distribution.

14. The non-transitory computer readable medium of claim 13, wherein compressing the data of the graph using the multi-context entropy coder comprises:
compressing the data of the graph using the multi-context entropy coder for storage in memory.

15. The non-transitory computer readable medium of claim 13, wherein compressing the data of the graph using the multi-context entropy coder comprises:
compressing the data of the graph using the multi-context entropy coder for transmission to at least one computing device.

16. The non-transitory computer readable medium of claim 13, wherein compressing the data of the graph using the multi-context entropy coder comprises:
compressing the data of the graph using a combination of Huffman coding and Asymmetric numeral systems (ANS).

17. The non-transitory computer readable medium of claim 13, further comprising:
obtaining a second graph having second data; and
compressing the second data of the graph using the multi-context entropy coder, wherein compressing the second data of the graph is performed simultaneously with compressing the data of the graph.

18. The non-transitory computer readable medium of claim 13, further comprising:
decompressing compressed data of the graph using a decoder, wherein the decoder is configured to decode data encoded by the multi-context entropy coder.

19. The non-transitory computer readable medium of claim 13, further comprising:
while compressing the data of the graph using the multi-context entropy coder, determining a processing speed associated with the multi-context entropy coder;
comparing the processing speed to a threshold processing speed; and
based on the comparing the processing speed to the threshold processing speed, adjusting operation of the multi-context entropy coder.

20. The non-transitory computer readable medium of claim 19, wherein based on the comparing the processing speed to the threshold processing speed, adjusting operation of the multi-context entropy coder comprises:
determining that the processing speed is below the threshold processing speed; and
based on determining that the processing speed is below the threshold processing speed, decreasing an operation rate of the multi-context entropy coder.
